(19) United States
(12) Patent Application Publication
(10) Pub. No.: US 2025/0291242 A1
(43) Pub. Date: Sep. 18, 2025

(54) PELLICLE CLEANING APPARATUS AND PELLICLE CLEANING METHOD

(71) Applicant: Samsung Electronics Co., Ltd., Suwon-si (KR)

(72) Inventors: Yoon Ki HWANG, Hwaseong-si (KR); Sung Won YOON, Suwon-si (KR); Dong Hun LEE, Suwon-si (KR)

(21) Appl. No.: 18/898,328

(22) Filed: Sep. 26, 2024

(30) Foreign Application Priority Data
Mar. 15, 2024 (KR) 10-2024-0036151

(51) Int. Cl. G03F 1/84; B08B 6/00; G03F 1/62

(52) U.S. Cl. CPC G03F 1/84; B08B 6/00; G03F 1/62

(57) ABSTRACT

A pellicle cleaning method includes loading a pellicle on a first surface of a stage, rotating the stage about an axis parallel to the first surface, electrifying a tip; and removing particles from the pellicle, wherein removing of the particles from the pellicle includes pushing of the particles on the pellicle with the electrified tip.

### CROSS-REFERENCE TO RELATED APPLICATION

This application claims priority to Korean Patent Application No. 10-2024-0036151 filed on Mar. 15, 2024, in the Korean Intellectual Property Office, the contents of which in their entirety are herein incorporated by reference.

### BACKGROUND

### 1. Field

The present disclosure relates to a pellicle cleaning apparatus and a pellicle cleaning method.

### 2. Description of the Related Art

As the degree of integration of semiconductor elements increases, the development of an exposure device that uses EUV (Extreme Ultra Violet) light having a shorter wavelength than DUV (Deep Ultra Violet) light as a light source is actively progressing to improve resolution. An EUV exposure device may use a reflective mask that utilizes the reflective properties of EUV light.

The reflective mask may be contaminated by particles when performing an exposure process by using the EUV exposure device. Therefore, a pellicle may be used on the reflective mask to protect the reflective mask.

### SUMMARY

According to an example embodiment of the present disclosure, a pellicle cleaning method includes loading a pellicle on a first surface of a stage, rotating the stage about an axis parallel to the first surface, electrifying a tip; and removing particles from the pellicle, wherein removing of the particles from the pellicle includes pushing of the particles on the pellicle with the electrified tip.

According to an example embodiment of the present disclosure, a pellicle cleaning method includes loading a pellicle onto an upper surface of a stage, adjusting a rotary angle of the stage around an axis parallel to the upper surface of the stage, removing particles from the pellicle, the removing of the particles from the pellicle including pushing the particles on the pellicle in a horizontal direction with a sharp tapered tip, determining whether the particles are removed from the pellicle, and removing the particles from the pellicle again, when the particles remain on the pellicle.

According to an example embodiment of the present disclosure, a pellicle cleaning apparatus includes a stage configured to support a pellicle on a first surface, a stage driver configured to rotate the stage about an axis parallel to the first surface, a probe which includes a cantilever and a tip provided at an end of the cantilever, a probe driver configured to move the probe in a vertical direction and a horizontal direction, and an electrostatic charger, wherein the tip is configured to contact with the electrostatic charger, be electrified by the probe driver, and push particles on the pellicle.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a diagram for explaining a pellicle cleaning apparatus according to some embodiments;

FIG. 2 is a flowchart for explaining a pellicle cleaning method according to some embodiments;

FIGS. 3 to 9 are diagrams for explaining the pellicle cleaning method according to some embodiments;

FIG. 10 is a flowchart for explaining the pellicle cleaning method according to some embodiments;

FIG. 11 is a diagram for explaining the pellicle cleaning apparatus according to some embodiments;

FIG. 12 is a flowchart for explaining the pellicle cleaning method according to some embodiments;

FIGS. 13 to 15 are diagrams for explaining the pellicle cleaning method according to some embodiments;

FIGS. 16 and 17 are diagrams for explaining the pellicle cleaning apparatus according to some embodiments; and

FIG. 18 is a diagram for explaining an extreme ultraviolet lithography apparatus using a pellicle and a photomask according to some embodiments.

### DETAILED DESCRIPTION OF THE EMBODIMENTS

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

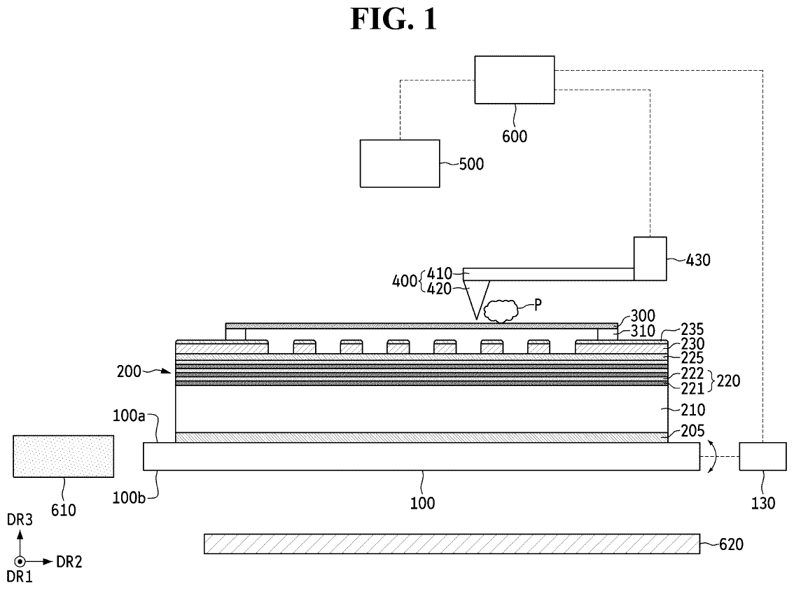

FIG. 1 is a diagram for explaining a pellicle cleaning apparatus according to some embodiments.

Referring to FIG. 1, the pellicle cleaning apparatus according to some embodiments includes a stage 100, a stage driving unit (e.g., a stage driver) 130, a probe 400, a probe driving unit (e.g., a probe driver) 430, an image capturing device (e.g., an image sensor) 500, a control unit (e.g., a controller) 600, an electrification member (e.g., an electrostatic charger) 610, and a collection member 620.

The stage 100 may include a first side/surface 100a and a second side/surface 100b that are opposite to each other. The first side/surface 100a and the second side/surface 100b may be opposite to each other in a third direction DR3. For example, the first surface 100a of the stage 100 may be an upper surface of the stage 100, and the second surface 100b of the stage 100 may be a lower surface of the stage 100. The stage 100 may support and fix an object to be inspected. The stage 100 may be a vacuum chuck or an electrostatic chuck.

The stage driving unit 130 drives the stage 100. The stage driving unit 130 may move the stage 100 in a first direction DR1, a second direction DR2, and the third direction DR3 under the control of the control unit 600. The stage driving unit 130 rotates the stage 100 with a direction parallel to the first side/surface 100a as a rotary axis. As used herein, “rotary axis” of the stage 100 in the present disclosure may be an axis of rotation of the stage 100 when the stage 100 is rotated. For example, under the control of the control unit 600, the stage driving unit 130 may rotate the stage 100 about an axis extending in the first direction DR1, or may rotate the stage 100 about an axis extending in the second direction DR2. The stage driving unit 130 may include, for example, an actuator such as an electric motor and/or a hydraulic motor. For example, the stage driving unit 130 may be a stage driver moving the stage 100 in the first, second, and third directions and rotating the stage about an axis extending in the first direction and/or about an axis extending in the second direction, e.g., by using an electric motor and/or a hydraulic motor.

The pellicle 300 is loaded onto the first side/surface 100a of the stage 100. The stage 100 may support the pellicle 300. The stage 100 may support the pellicle 300 coupled to a pellicle frame 310. The pellicle frame 310 may be formed near the corner of the pellicle 300. The pellicle frame 310 may connect the pellicle 300 to the stage 100. For example, an adhesive layer may be disposed between the pellicle frame 310 and the pellicle 300 and/or between the pellicle frame 310 and the photomask 200.

The pellicle 300 may be a membrane that protects the photomask 200 used in an exposure process for fabricating semiconductor devices. For example, the pellicle 300 may be used to protect the pattern of the photomask 200 in an EUV exposure device. The pellicle 300 may protect the pattern of the photomask 200 from contamination. The pellicle 300 may be used as various pollution prevention filters. For example, when the pellicle 300 is used to protect the photomask 200, the pellicle 300 may include carbon. For example, the pellicle 300 may include graphite, graphene, carbon nanotube (CNT), nanohorn, nano carbon flake, nanocrystalline graphite, amorphous carbon, diamond-like carbon (DLC), hydrocarbon and/or graphene oxide. In addition, the pellicle 300 may include various materials that are transparent to EUV wavelengths. For example, the pellicle 300 may include molybdenum (Mo), ruthenium (Ru), zirconium (Zr), zirconium carbide (ZrC), boron (B), boron carbide (BxCy), boron nitride (BN), titanium (Ti), tungsten (W), tungsten sulfide (WxSy), niobium (Nb), aluminum (Al), tin (Sn), zinc (Zn), and/or nickel (Ni). If the pellicle 300 is used for other applications, it may include other materials suitable for applications.

The probe 400 includes a cantilever 410, and a tip 420 provided at an end of cantilever 410. The cantilever 410 may be a plate-shaped spring that is easily warped by a minute force of, for example, several nano newtons (N). The tip 420 may be connected to the end of the cantilever 410.

In some embodiments, the tip 420 has a tapered shape with one end pointed. The width of the tip 420 may increase in a direction approaching the cantilever 410. For example, the width of the tip 420 may be measured in a direction parallel to a lengthwise direction of the cantilever 410.

The probe driving unit 430 drives the probe 400. The probe driving unit 430 may move the probe 400 in a first direction DR1, a second direction DR2, and a third direction DR3 by the control of the control unit 600.

The probe 400 may be moved onto the electrification member 610 by the probe driving unit 430. The tip 420 may be brought into contact with the electrification member 610 by the probe driving unit 430. For example, the probe driving unit 430 may be a probe driver moving the probe 400 in the first, second, and third directions DR1, DR2 and DR3, e.g., by using an electric motor and/or a hydraulic motor.

In some embodiments, the pellicle cleaning apparatus may be a part of an atomic force microscope (AFM). The pellicle cleaning apparatus may sense a surface to be inspected with a sensitivity at the level of individual atoms on the surface of the inspection target. The probe driving unit 430 may scan the inspection target (for example, the mask pattern 200) by moving the probe 400 in the first direction DR1 and/or the second direction DR2. While scanning the inspection target, the tip 420 is deflected by gravity or repulsive force from features on the surface of the inspection target. The deflection of the tip 420 causes the cantilever 410 to warp. The warpage of the cantilever 410 may be detected by an optical lever made up of a laser device, a photodetector, or the like.

The image capturing device 500 may be disposed on the pellicle 300. The image capturing device 500 captures the image of one side of the pellicle 300. Image information about one side of the pellicle 300 acquired by the image capturing device 500 is provided to the control unit 600. The image capturing device 500 may include, for example, an image sensor or the like.

The control unit 600 controls the pellicle cleaning apparatus. The control unit 600 may control the stage driving unit 130, the probe driving unit 430, the image capturing device 500, and the like. The control unit 600 may be provided with information about the particles P on the pellicle 300 (for example, the number of particles, the position of the particles, the size of the particles, etc.) from the outside.

The control unit 600 may be implemented as hardware, firmware, software, or any combination thereof. For example, the control unit 600 may include a computing device such as a workstation computer, a desktop computer, a laptop computer, and a tablet computer. The control unit 600 may include a microprocessor, a complex processor such as a CPU or a GPU, a processor configured by software, dedicated hardware, or firmware. The control unit 600 may be implemented by, for example, a general-purpose computer or application-specific hardware such as a DSP (Digital Signal Processor), an FPGA (Field Programmable Gate Array), and an ASIC (Application Specific Integrated Circuit). For example, the operations of the control unit 600 may be implemented as instructions stored on a machine-readable medium that may be read and executed by one or more processors. Here, the machine-readable medium may include any mechanism for storing and/or transmitting information in the form that is readable by a machine (e.g., a computing device). For example, the machine-readable media may include a read-only memory (ROM), a random access memory (RAM), a magnetic disk storage media, an optical storage media, flash memory devices, electrical, optical, acoustic or other forms of radio signals (e.g., carrier waves, infrared signals, digital signals, etc.) and any other signals. Alternatively, the control unit 600 may originate from a computing device, processor, firmware, software, other devices that execute routines, instructions, and the like.

The electrification member 610 may be a positive charge electrification member or a negative charge electrification member. The positive charge electrification member may be implemented by a material that is easily electrified to a positive charge from the order of electrification. The order of electrification in the present application may be the list of materials in the triboelectric series (the electrostatic series). The positive charge electrification member may include, for example, nylon, polypropylene, and the like. The negative charge electrification member may be implemented by a material that is easily electrified to a negative charge from the order of electrification. The negative charge electrification member may include, for example, polyethylene, Teflon, polytetrafluoroethylene, and the like. The tip 420 may be electrified to a positive charge or a negative charge by coming into contact with the electrification member 610. The pellicle cleaning apparatus according to some embodiments may include one of the positive charge electrification member and the negative charge electrification member. The pellicle cleaning apparatus according to some embodiments may include the positive charge electrification member and the negative charge electrification member. For example, the electrification member 610 may be an electrostatic charger configured to charge the tip 420 with positive charge or with negative charge. For example, the electrostatic charger may include an electrostatic generator that produces static electricity, e.g., an influence machine or a friction machine.

A collection member 620 may be disposed on the stage 100. The collection member 620 may be a member for collecting the particles falling from the pellicle 300. Therefore, it is possible to prevent contamination of the pellicle cleaning apparatus due to particles removed from the pellicle 300. For example, the collection member 620 may be a particle collector, e.g., made of a metal or a plastic (e.g., a tray, a bowl or a container for collecting particles removed from the pellicle 300). The collection member 620 may be moved by a driving unit driven by the control of the control unit 600, and the particles on the collection member 620 may be discharged to the outside of the pellicle cleaning apparatus, accordingly.

The pellicle cleaning apparatus may remove particles P by pushing the particles P on the pellicle 300 with the tip 420. The pellicle cleaning apparatus according to some embodiments removes particles P on the pellicle 300 in the state in which the pellicle 300 is disposed on the photomask 200. The pellicle 300 may be disposed on the photomask 200.

The photomask 200 may include a conductive layer 205, a mask substrate 210, a reflective layer 220, a capping layer 225, an absorption pattern 230, and an anti-reflective coating layer 235 that are stacked in sequence.

The conductive layer 205 may be used to attach the photomask 200 to the stage 100. The conductive layer 205 may include a chromium (Cr)-containing material or a tantalum (Ta)-containing material that has conductivity (e.g., electrical conductivity). For example, the conductive layer 205 may be made of at least one of Cr, CrN or TaB. Alternatively, the conductive layer 205 may include a metal oxide or metal nitride that has conductivity (e.g., electrical conductivity). For example, the conductive layer 205 may include at least one of titanium nitride (TiN), zirconium nitride (ZrN), hafnium nitride (HfN), ruthenium oxide (RuO2), zinc oxide (ZnO2) or iridium oxide (IrO2).

A mask substrate 210 may be formed on the conductive layer 205. The mask substrate 210 may include a material with a low coefficient of thermal expansion (low thermal expansion material: LTEM). Further, the mask substrate 210 may include a material with excellent smoothness, flatness, and resistance to cleaning liquid. For example, the mask substrate 210 may include, but not limited to, synthetic silica glass, silica glass, alumina silicate glass, soda lime glass, and/or SiO₂—TiO₂-based glass.

The reflective layer 220 may be formed on the mask substrate 210. The reflective layer 220 may be configured to reflect light incident on the photomask 200. The reflective layer 220 may include, for example, a Bragg reflector in which a first material layer 221 having a high refractive index and a second material layer 222 having a low refractive index are alternately stacked multiple times. The first material layer 221 and the second material layer 222 may be repeatedly formed at about 20 to 80 cycles. For example, the reflective layer 220 may include a molybdenum (Mo)/silicon (Si) periodic multi film, a Mo compound/Si compound periodic multi film, a ruthenium (Ru)/Si periodic multi film, a beryllium (Be)/Mo periodic multi film, a Si/Niobium (Nb) periodic multi film, a Si/Mo/Ru periodic multi film, a Si/Mo/Ru/Mo periodic multi film or a Si/Ru/Mo/Ru periodic multi film. For example, a period of the periodic mufti film may range from two layers to four layers of materials. The respective materials forming the first material layer 221 and the second material layer 222 and the respective thicknesses of the first material layer 221 and the second material layer 222 may be adjusted depending on the wavelength of light (for example, extreme ultraviolet rays) incident on the reflective layer 220 and/or the reflectance of light (for example, extreme ultraviolet rays) required for the reflective layer 220. For example, the first material layer 221 may include molybdenum, and the second material layer 222 may include silicon.

A capping layer 225 may be formed on the reflective layer 220. The capping layer 225 may include, for example, ruthenium oxide (RuO) or the like. In certain embodiments, the capping layer 225 may be omitted.

An absorption pattern 230 may be formed on the capping layer 225. The absorption pattern 230 may be configured to absorb at least some of the light incident on the photomask 200. The absorption pattern 230 may include an opening that exposes at least a part of capping layer 225. The absorption pattern 230 may include, for example, but not limited to, at least one of TaN, TaHf, TaHfN, TaBSi, TaBSiN, TaB, TaBN, TaSi, TaSiN, TaGe, TaGeN, TaZr, and TaZrN.

An anti-reflective coating layer 235 may be formed on the absorption pattern 230. The anti-reflective coating layer 235 may include, for example, a metal nitride, such as a transition metal nitride, such as titanium nitride or tantalum nitride, or may further contain one or more additional ingredients selected from a group consisting of chlorine, fluorine, argon, hydrogen and oxygen. In certain embodiments, the anti-reflection coating layer 235 may be omitted.

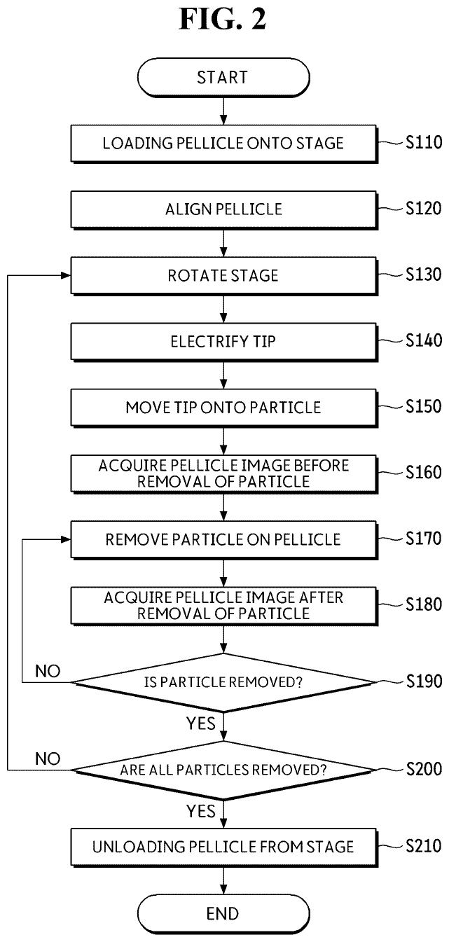

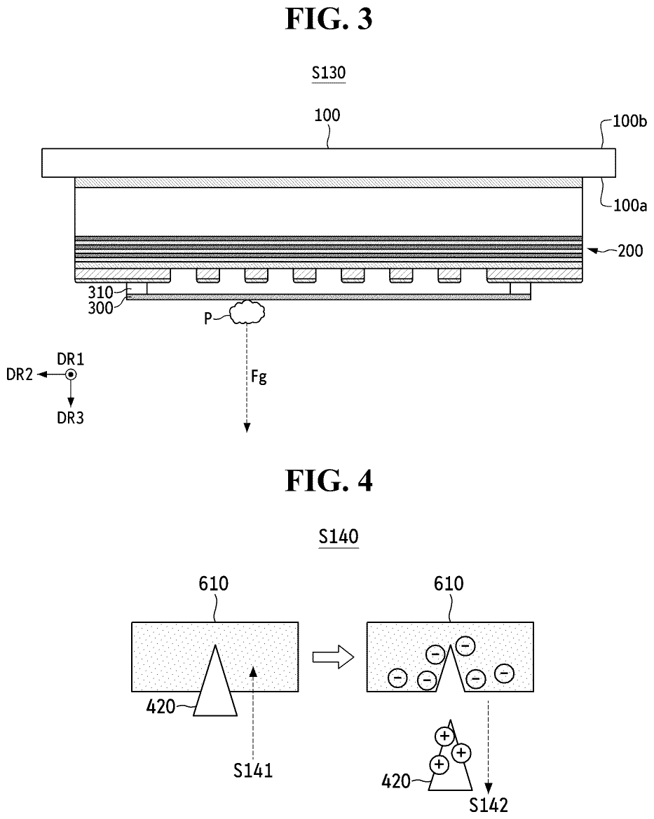

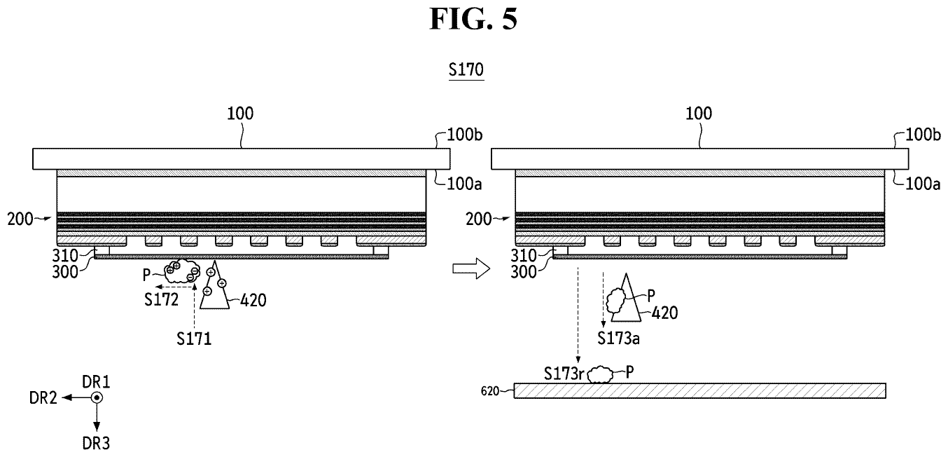

FIG. 2 is a flowchart for explaining a pellicle cleaning method according to some embodiments. FIGS. 3 to 9 are diagrams for explaining the pellicle cleaning method according to some embodiments.

Referring to FIG. 2, a pellicle is loaded onto the stage (S110). In some embodiments, loading (S110) of the pellicle onto the stage includes loading of a pellicle mounted on a photomask onto the stage.

For example, referring to FIG. 1, a pellicle 300 may be loaded onto the first side 100a of the stage 100. In some embodiments, the photomask 200 and the pellicle 300 may be loaded onto the first side 100a of the stage 100. The pellicle 300 may be fixed onto the photomask 200.

Referring to FIG. 2 again, the pellicle 300 is aligned (S120).

For example, referring to FIG. 1, the photomask 200 with the pellicle 300 mounted thereon may include marks for global alignment. The photomask 200 on which the pellicle 300 is stacked/attached may be aligned, using the marks. The control unit 600 may receive information about the particles P on the pellicle 300 from the outside. The information may include, for example, coordinates of the particles P on the pellicle 300. When there are multiple particles P, the information may include coordinates of each particle P on the pellicle 300. The control unit 600 may determine the position of the particle P on the pellicle 300 on the basis of the alignment of the pellicle 300 and the received coordinates of the particles P. For example, the control unit 600 may correct the received coordinates of the particles P, using the alignment error/deviation of the pellicle 300.

Referring to FIG. 2 again, the stage is rotated (S130).

For example, referring to FIG. 1, a rotary angle (an angle of rotation) of the stage 100 may be adjusted, with a direction (for example, the first direction DR1) parallel to the first side 100a of the stage 100 as a rotary axis. The control unit 600 may determine the rotary angle of the stage 100. Under the control of the control unit 600, the stage driving unit 130 may rotate the stage 100 at the predetermined rotary angle, with the direction parallel to the first side 100a of the stage 100 as the rotary axis.

The stage 100 may be rotated at various angles. The particle P may receive a first force Fg, which is gravity, in the direction of gravity. As the stage 100 rotates, the particles P may receive gravity in a direction that is not directed toward the pellicle 300. For example, referring to FIG. 3, the stage 100 may rotate 180 degrees with the first direction DR1 as the rotary axis, and the particles P may receive the first force Fg in the direction of gravity (for example, the third direction DR3).

Referring to FIG. 2 again, the tip is electrified (S140).

For example, referring to FIGS. 1, 2, and 4, the tip 420 may be electrified to the positive charge or negative charge, by coming into contact with the electrification member 610 by the probe driving unit 430. Electrifying (S140) of the tip 420 may include bringing the tip 420 into contact with the electrification member 610 to electrify the tip 420 (S141), and separating of the tip 420 from the electrification member 610 (S142). For example, under the control of the control unit 600, the probe driving unit 430 may move the probe 400 onto the electrification member 610, bring the probe 400 closer to the electrification member 610, and indent the tip (420) into the electrification member 610 (S141). Accordingly, the tip 420 may be electrified to the positive charge or negative charge. The probe driving unit 430 may separate the tip 420 from the electrification member 610 under the control of the control unit 600 (S142).

Referring to FIG. 2 again, the tip is moved onto the particle (S150).

For example, referring to FIG. 1, the probe driving unit 430 may move the probe 400 onto the particle P under the control of the control unit 600. Accordingly, the tip 420 may be moved onto the particle P.

For example, the control unit 600 may determine the position of the tip 420, at which the tip 420 moves in the third direction DR3 and is disposed on one side of the particle P. For example, the control unit 600 may adjust a distance in a horizontal direction between the particle P and the tip 420. The probe driving unit 430 may move the tip 420 onto the determined position. The tip 420 may be in a state of being spaced apart from the determined position in the third direction DR3. The tip 420 may be aligned at the determined position on a plane including the first direction DR1 and the second direction DR2. Here, the horizontal direction is a direction that is perpendicular to the direction of gravity in which gravity acts. For example, the horizontal direction may be the first direction DR1 and/or the second direction DR2 in FIG. 1.

Referring to FIG. 2 again, a pellicle image before the particle removal is acquired (S160).

For example, referring to FIG. 1, the image capturing device 500 may capture an image of the pellicle 300. The control unit 600 may be provided with an image of the pellicle 300 before removing the particles P from the image capturing device 500, and may store the image.

Referring to FIG. 2 again, particles on the pellicle are removed (S170). Removal (S170) of particles on the pellicle includes pushing of the particles with the tip. The removal (S170) of the particles on the pellicle is performed after rotating of the stage (S130) and the electrifying of the tip (S140).

For example, referring to FIGS. 1, 2, 5, and 6, the tip 420 may be moved in the horizontal direction to remove the particles P on the pellicle 300. Removal (S170) of the particles P on the pellicle 300 may include moving (S171) of the tip 420 to one side of the particle P, moving (S172) of the tip 420 in the horizontal direction to push the particle P in the horizontal direction, and removal (S173a, S173r) of the particles P from the pellicle 300. For example, the tip 420 may move in the third direction DR3 and move to one side of the particle P by the probe driving unit 430 (S171). For example, the tip 420 may be moved in the third direction DR3 and aligned at the determined position. The probe driving unit 430 allows the tip 420 to move in the horizontal direction and push the particles P in the horizontal direction (S172). Accordingly, the particles P may be removed from the pellicle 300 (S173a, S173r).

For example, the control unit 600 may determine movement conditions. The movement conditions may include the movement direction of the tip 420, the moving speed of the tip 420, and/or the time at which the tip 420 moves and the time at which the tip 420 stops when the tip 420 repeatedly moves and stops. The movement direction of the tip 420 is a movement direction in the horizontal direction. The tip 420 may move depending on the movement conditions determined by the probe driving unit 430 (for example, depending on the determined moving speed in the determined movement direction), and as the tip 420 moves in the horizontal direction, the particles P may be removed from the pellicle 300.

As the tip 420 moves in the horizontal direction by the probe driving unit 430, the tip 420 may push the particle P in the horizontal direction. The particle P may receive a second force Fm in the horizontal direction. Further, an attractive force or a repulsive force may act between the electrified tip 420 and the particle P. Accordingly, a third force Fe may occur between the tip 420 and the particle P.

The first force Fg due to gravity, the second force Fm due to movement of the tip 420, and the third force Fe due to the attractive force or repulsive force between the electrified tip 420 and the particle P may act on the particle P. If the sum of the first force Fg, the second force Fm, and the third force Fe is greater than the adhesive force Fa between the particle P and the pellicle 300, the particle P may be removed from the pellicle 300.

When the attractive force acts between the electrified tip 420 and the particle P, the particle P may be stuck to the tip 420 and removed from the pellicle 300 (S173a), and when the repulsive force acts between the electrified tip 420 and the particle P, the particles P may fall in the direction of gravity and be removed from the pellicle 300 (S173r). The particles P may fall into the collection member 620. Accordingly, contamination of the pellicle cleaning apparatus caused by particles P can be prevented.

The first force Fg may be calculated using Equation 1. In Equation 1, mₚ is the mass of the particle P, and g is the gravitational acceleration.

$${F}_{g} = {m}_{p} g \qquad [ Equation 1 ]$$

The second force Fm may be calculated using Equation 2. In Equation 2, mₚ may be the mass of the probe 400, and a may be the acceleration of the probe 400. The control unit 600 may control the second force Fm acting on the particle P by adjusting the acceleration of the probe 400.

$${F}_{m} = {m}_{pb} a \qquad [ Equation 2 ]$$

The third force Fe may be calculated using Equation 3. In Equation 3, k is a Coulomb constant, r is a distance between the tip 420 and the particle P, q₁ is an amount of charge of the tip 420, and q₂ may be an amount of charge of the particle P. The control unit 600 may adjust at least one of the distance between the particle P and the tip 420, the amount of charge of the particle P, and the amount of charge of the tip 420 to control the third force Fe between the particle P and the tip 420.

$${F}_{e} = k \frac{{q}_{1} {q}_{2}}{{r}^{2}} \qquad [ Equation 3 ]$$

The adhesive force Fa between the particle P and the pellicle 300 may be calculated using Equation 4. In Equation 4, A is a Hammer constant, R is a radius of the spherical particle P, z₀ is a distance between the particle P and the pellicle 300, and a may be a contact radius between the article P and the pellicle 300.

$${F}_{a} = \frac{AR}{6 {z}_{0}^{2}} ( 1 + \frac{{a}^{2}}{{Rz}_{0}} ) \qquad [ Equation 4 ]$$

Referring to FIG. 2 again, a pellicle image is acquired after the particle removal (S180). It is determined whether particles are removed from the pellicle (S190). In some embodiments, when the particles are not removed from the pellicle (S190), the process returns to step S170 and the removal of particles on the pellicle is performed again.

When the particles are removed from the pellicle (S190), it is determined whether all particles on the pellicle are removed (S200). When all particles on the pellicle are not removed (S190), the process returns to step S130 and the stage is rotated again. When all particles on the pellicle are removed (S190), the pellicle is unloaded from the stage (S210).

For example, referring to FIG. 1, the image capturing device 500 may capture an image of the pellicle 300. The control unit 600 may be provided with an image of the pellicle 300 after removing the particles P from the image capturing device 500, and may store the image.

The control unit 600 compares the image of the pellicle 300 before removing the particles P (the image acquired in step S160) with the image of the pellicle 300 after removing the particles P (the image acquired in the step S160), and may determine whether the particles P are removed from the pellicle 300. When a particle P attempted to be removed from the pellicle 300 in step S170 remains on the pellicle 300, the control unit 600 may determine that the particle P is not removed from the pellicle 300, and when the particle P attempted to be removed from the pellicle 300 in step S170 does not remain on the pellicle 300, the control unit 600 may determine that the particle P is removed from the pellicle 300.

If it is determined in step S170 that the particle P attempted to be removed from the pellicle 300 is not removed, the pellicle cleaning apparatus may return to step S170 to remove the particle P again. The tip 420 may push back the particle P in the horizontal direction again.

For example, the control unit 600 may maintain the movement conditions determined in the previous step S170, and the tip 420 may be driven again according to the movement conditions to push the particle P. As another example, the control unit 600 may change the movement conditions determined in step S170, and the tip 420 may be driven according to the changed movement conditions to push the particle P again. As yet another example, the control unit 600 may change the position determined in step S130, and the tip 420 may be driven at the changed position according to the movement condition or the changed movement condition and may push the particle P again.

When it is determined in step S170 that the particle P attempted to be removed from the pellicle 300 is removed, the control unit 600 may determine whether all particles P on the pellicle 300 are removed on the basis of information about the particles received in step S120.

When it is determined in step S200 that all the particles P on the pellicle 300 are not removed, the pellicle cleaning apparatus may return to step S130 and rotate the stage 100 again. For example, the pellicle cleaning apparatus may remove the next particle P. Steps S130 to S200 may be executed for each particle P on the pellicle 300.

For example, the control unit 600 may determine the rotary angle of the stage 100 performed in step S130, the amount of charge of electrification of the tip 420 performed in step S140, the position of the tip 420 moved in step S150, the movement direction of tip 420 and/or the moving speed of the tip 420 performed in step S170, and the like for each particle P, thereby removing each particle P from the pellicle 300.

When it is determined in step S200 that all particles P on the pellicle 300 are removed, the pellicle 300 may be unloaded from the stage 100.

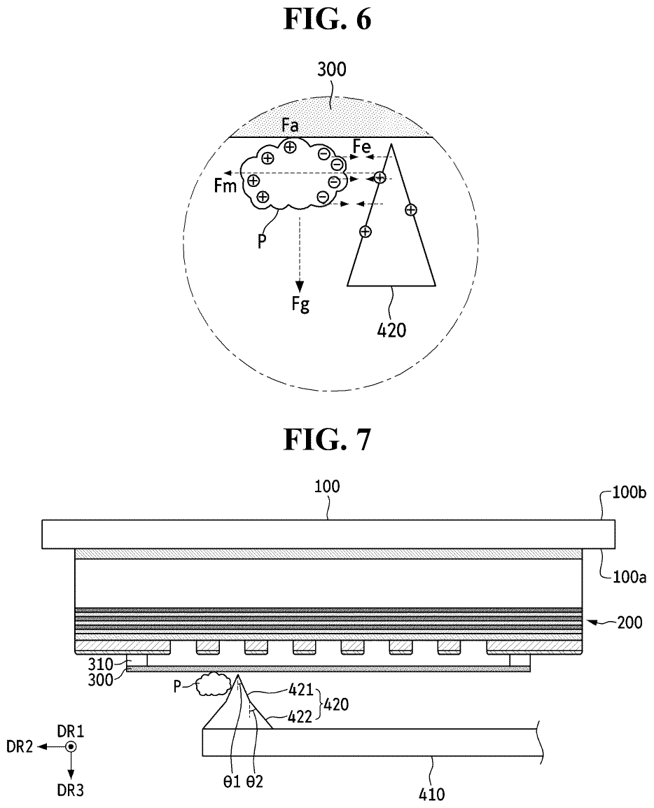

The pellicle cleaning method according to some embodiments removes the particles P from the pellicle 300, by using the first force Fg, the second force Fm, and the third force Fe. At this time, the first force Fg, the second force Fm, and the third force Fe all act in a direction that is not directed toward the pellicle 300. For example, referring to FIG. 6, the first force Fg acts in the direction of gravity, and the second force Fm and the third force Fe act in a direction parallel to the surface of the pellicle 300. Further, in the pellicle cleaning method according to some embodiments, the magnitudes of the first force Fg, the second force Fm, and the third force Fe may be controlled for each particle P on the pellicle 300. Therefore, the pellicle cleaning method according to some embodiments may more efficiently remove particles P on the pellicle 300 without damaging the pellicle 300.

FIGS. 7 to 9 are diagrams for explaining the pellicle cleaning apparatus according to some embodiments. For convenience of explanation, repeated parts of those explained above using FIGS. 1 to 6 will be briefly explained or omitted.

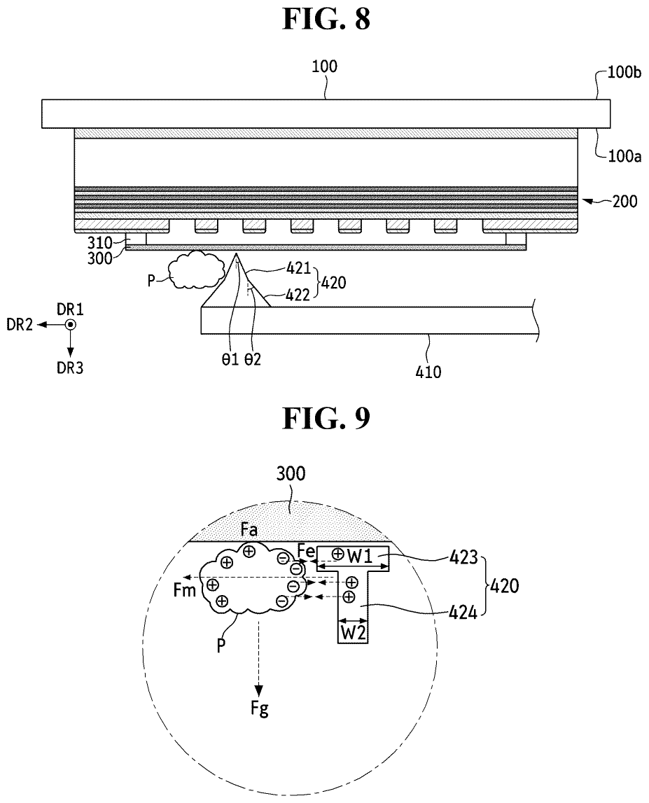

Referring to FIGS. 7 and 8, in the pellicle cleaning apparatus according to some embodiments, the tip 420 includes a first portion 421 and a second portion 422 that have different slopes of side walls and are connected to each other. A slope or first angle θ1 of the side wall of the first portion 421 is different from a slope or second angle θ2 of the side wall of the second portion 422 with respect to the third direction DR3. The slope or first angle θ1 of the side wall of the first portion 421 may be smaller than the slope or second angle θ2 of the side wall of the second portion 422. The second portion 422 may connect the first portion 421 and a cantilever 410. The first portion 421 may be or include the end of the tip 420.

The pellicle cleaning apparatus may remove the particles P, by pushing the particles P with at least one of the first portion 421 and the second portion 422 of the tip 420, depending on the size of the particles P.

Removal (S170) of the particles on the pellicle of FIG. 2 may include determining whether the size of the particle P is equal to or less than a set value, pushing the particle P with the first portion 421 of the tip 420 when the size of the particle P is equal to or less than the set value, and pushing the particle P with the second portion 422 and/or the first portion 421 of the tip 420 when the size of the particle P exceeds the above set value.

For example, referring to FIG. 1, the control unit 600 may determine whether the size of the particle P is equal to or less than a set value. For example, information about the particles P on the pellicle 300 received from the outside may include information about the size of the particles P. The control unit 600 may determine whether the size of the particle P is equal to or less than the set value on the basis of the information.

Referring to FIG. 7, when the size of the particle P is equal to or less than the set value, the first portion 421 of the tip 420 may push the particle P as the tip 420 moves in the horizontal direction. The particles P may be removed by pushing the particles P with the first portion 421 of the tip 420.

Referring to FIG. 8, when the size of the particle P exceeds the above set value, the second portion 422 and/or the first portion 421 of the tip 420 may push the particle P as the tip 420 moves in the horizontal direction. The particles P may be removed, by pushing the particles P with the second portion 422 and/or the first portion 421 of the tip 420.

Referring to FIG. 9, in the pellicle cleaning apparatus according to some embodiments, the tip 420 may have a hammer shape. The tip 420 may include a third portion 423 and a fourth portion 424 that are connected to each other. The fourth portion 424 may connect the third portion 423 and the cantilever (410 of FIG. 1). A width W1 of the third portion 423, e.g., in a horizontal direction, may be greater than a width W2 of the fourth portion 424, e.g., in the horizontal direction. For example, the horizontal direction may be the same direction as a direction that the cantilever 410 extends lengthwise. The pellicle cleaning apparatus may remove the particles P, by pushing the pellicle 300 with the third portion 423 of the tip 420. Additionally, the shape of the tip 420 may vary.

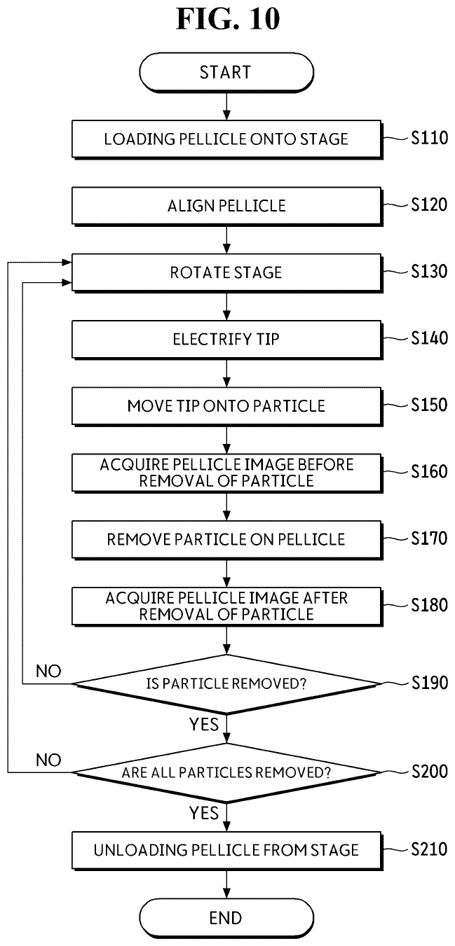

FIG. 10 is a flowchart for explaining a pellicle cleaning method according to some embodiments. For convenience of explanation, repeated parts of those explained above using FIGS. 1 to 9 will be briefly explained or omitted.

Referring to FIG. 10, in some embodiments, when the particles are not removed from the pellicle (S190), the process returns to step S130 and the stage is rotated again. Steps S130 to S190 may be performed again, when the particles are not removed from the pellicle.

The control unit 600 may readjust the magnitudes of the first force Fg, the second force Fm, and the third force Fe acting on the particle P, thereby removing the particles P from the pellicle 300 again.

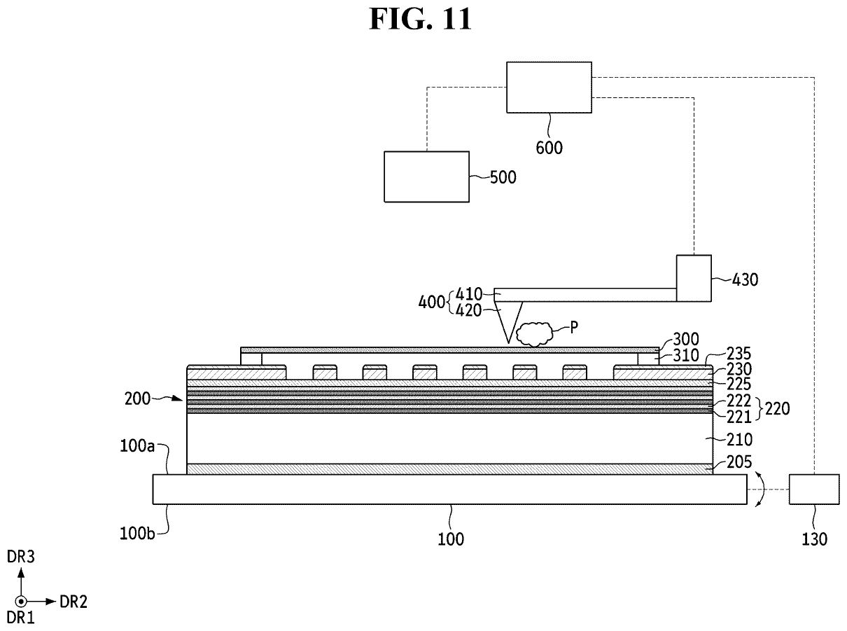

FIG. 11 is a diagram for explaining the pellicle cleaning apparatus according to some embodiments. For convenience of explanation, repeated parts of those explained above using FIGS. 1 to 9 will be briefly explained or omitted.

Referring to FIG. 11, the pellicle cleaning apparatus according to some embodiments includes a stage 100, a stage driving unit 130, a probe 400, a probe driving unit 430, an image capturing device 500, and a control unit 600. For example, the electrification member 610 and the collection member 620 of FIG. 1 may be omitted.

The pellicle cleaning apparatus according to some embodiments may include the stage 100, the stage driving unit 130, the probe 400, the probe driving unit 430, the image capturing device 500, the control unit 600, and the collection member 620. For example, the electrification member 610 of FIG. 1 may be omitted.

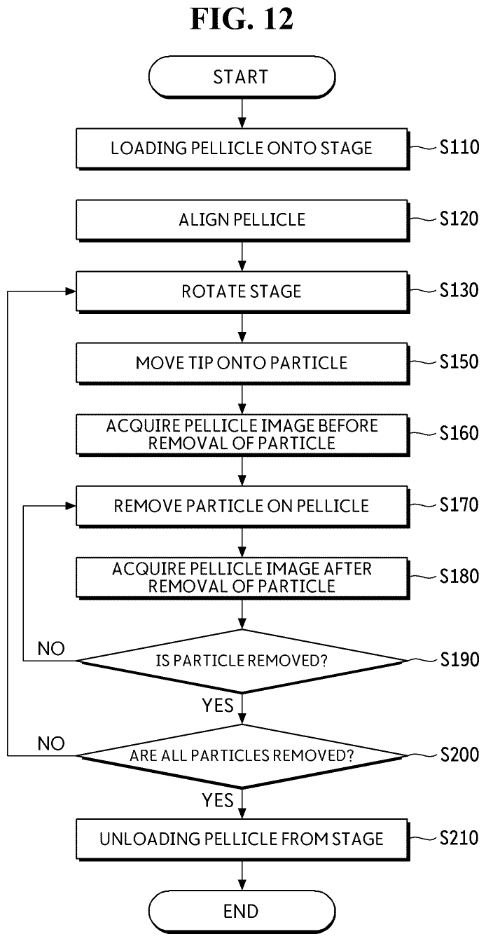

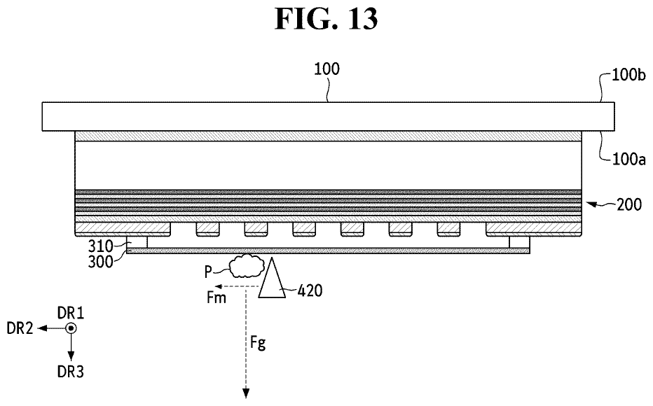

FIG. 12 is a flowchart for explaining a pellicle cleaning method according to some embodiments. FIGS. 13 to 15 are diagrams for explaining a pellicle cleaning method according to some embodiments. For convenience of explanation, repeated parts of those explained above using FIGS. 1 to 9 will be briefly explained or omitted.

Referring to FIG. 12, the stage is rotated (S130), the tip is moved onto the particles (S150), a pellicle image before the particle removal is acquired (S160), and particles on the pellicle are removed (S170). For example, step S140 of FIG. 2 may be omitted in certain cleaning methods.

For example, referring to FIG. 11, the stage 100 may rotate at various angles. The non-electrified tip 420 is may be moved in the horizontal direction by the probe driving unit 430, and the particles P may be removed from the pellicle 300 as the non-electrified tip 420 moves in the horizontal direction.

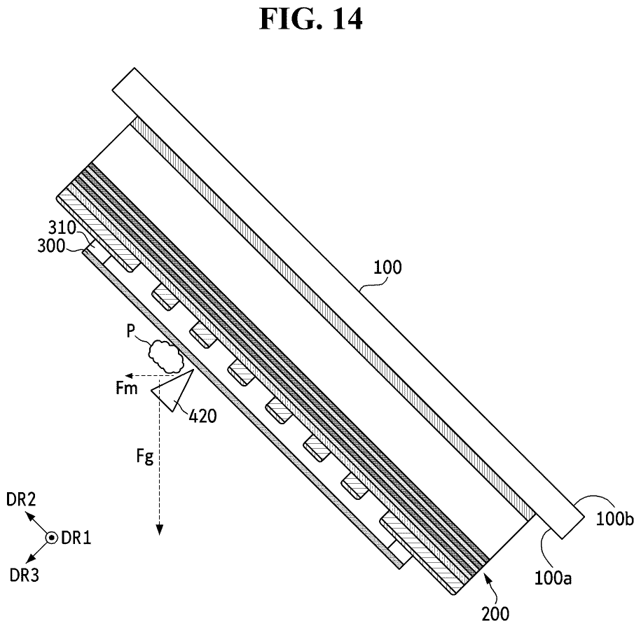

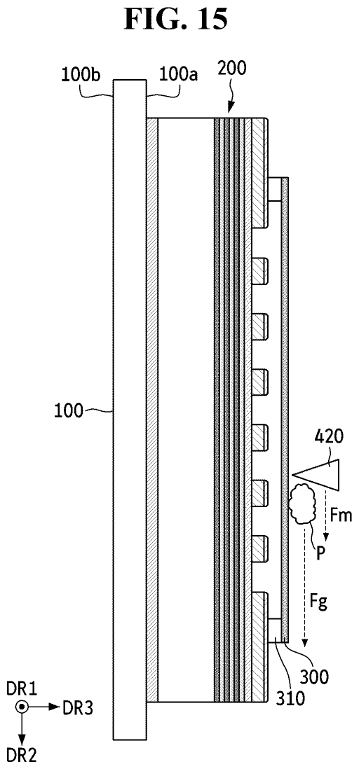

The stage 100 may rotate at various angles. For example, referring to FIG. 13, the stage 100 may rotate by 180 degrees around an axis parallel to the first side/surface 100a of the stage 100 (for example, extending in the first direction DR1) as the rotary axis. Referring to FIG. 14, the stage 100 may rotate by 225 degrees clockwise around an axis parallel to the first side/surface 100a of the stage 100 (for example, extending in the first direction DR1) as the rotary axis. Referring to FIG. 15, the stage 100 may rotate 90 degrees clockwise around an axis parallel to the first side/surface 100a of the stage 100 (for example, extending in the first direction DR1) as the rotary axis.

Referring to FIGS. 13 to 15, the tip 420 may push the particle P in the horizontal direction (for example, in the second direction DR2). Accordingly, the particle P may receive the first force Fg in the vertical direction and the second force Fm in the horizontal direction. As the tip 420 moves in the horizontal direction, the particles P may be removed from the pellicle 300. When the sum of the first force Fg and the second force Fm is greater than an adhesive force between the particle P and the pellicle 300, the particles P may be removed from the pellicle 300.

The pellicle cleaning method according to some embodiments removes the particles P from the pellicle 300, by using the first force Fg and the second force Fm that act in a direction that is not directed toward the pellicle 300. Further, in the pellicle cleaning method according to some embodiments, the magnitudes of the first force Fg and the second force Fm may be controlled for each particle P on the pellicle 300. Therefore, the pellicle cleaning method according to some embodiments may more efficiently remove the particles P from the pellicle 300 without damaging the pellicle 300.

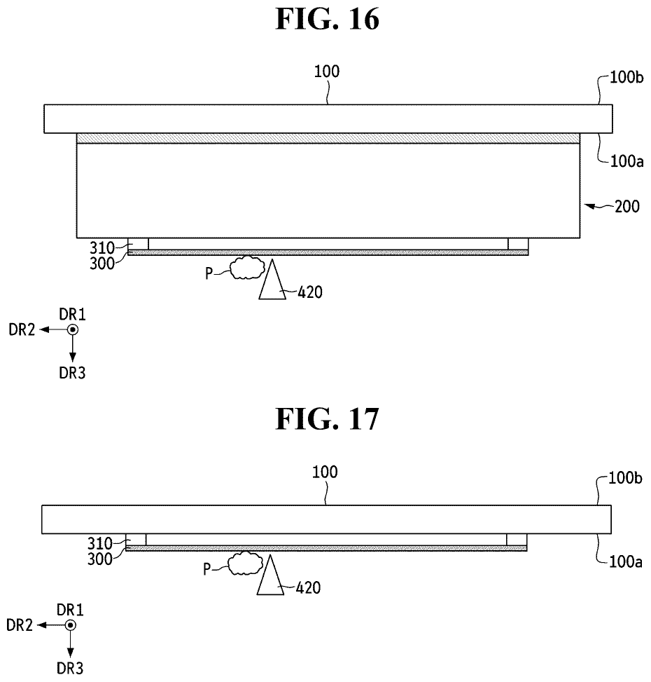

FIGS. 16 and 17 are diagrams for explaining the pellicle cleaning apparatus according to some embodiments.

Referring to FIG. 16, the pellicle cleaning apparatus according to some embodiments removes the particles P from the pellicle 300 disposed on a dummy mask 200D. For example, the pellicle 300 may be disposed on the dummy mask 200D.

In the pellicle cleaning method of FIGS. 2, 10, and 12, loading (Si 10) of the pellicle onto the stage includes loading of the pellicle 300 mounted on the dummy mask 200D onto the stage 100. The pellicle 300 may be fixed onto the dummy mask 200D. The dummy mask 200D may include, for example, a conductive layer and a mask substrate that are sequentially stacked on the first side/surface 100a of the stage 100.

Referring to FIG. 17, the pellicle cleaning apparatus according to some embodiments removes the particles P from the pellicle 300 directly disposed on the stage 100. For example, the pellicle 300 may be disposed on the stage 100.

In the pellicle cleaning methods of FIGS. 2, 10, and 12, loading (S110) of the pellicle onto the stage includes loading of the pellicle 300 directly onto the first side/surface 100a of the stage 100. The pellicle 300 may be directly fixed onto the first side/surface 100a of the stage 100. It will be understood that when an element is referred to as being “disposed on” another element, it can be directly disposed on the other element or intervening elements may be present. In contrast, when an element is referred to as being “directly disposed” on another element, there are no intervening elements present between the two elements.

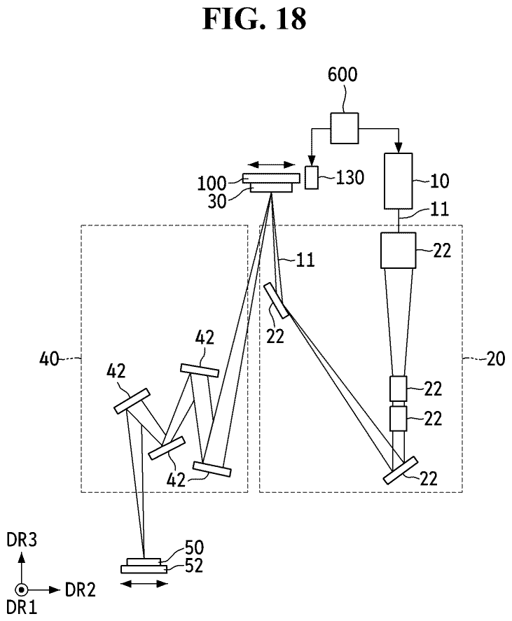

FIG. 18 is a diagram for explaining an extreme ultraviolet lithography apparatus that uses a pellicle and a photomask according to some embodiments.

Referring to FIG. 18, the extreme ultraviolet lithography apparatus according to some embodiments may include a light source unit (e.g., a light source) 10, a condensing unit (e.g., a condenser) 20, a projection unit (e.g., a projector) 40, and a control unit (e.g., a controller) 600.

The light source unit 10 may generate light 11. In some embodiments, the light 11 may include or may be extreme ultraviolet ray (EUV). For example, the light source unit 10 may generate extreme ultraviolet light having a wavelength of about 13.5 nm, by using plasma generated by irradiating tin (Sn) with a CO₂ laser. The light 11 generated from the light source unit 10 may be provided to the condensing unit 20.

The condensing unit 20 may guide the light 11 (e.g., extreme ultraviolet rays) generated from the light source unit 10 toward a mask assembly 30. The mask assembly 30 may include the photomask 200 and the pellicle 300 of FIGS. 1 to 17. The pellicle 300 may be in a state in which particles are removed by the pellicle cleaning method described above using FIGS. 1 to 17. A semiconductor element may be formed, using the pellicle 300 from which particles are removed by the pellicle cleaning method described above using FIGS. 1 to 17.

The condensing unit 20 may include a condensing optical system 22 (e.g., a lens and/or a mirror). The condensing optical system 22 may collect and reflect the light 11 and guide the light toward the mask assembly 30. The light 11 may be obliquely incident on the mask assembly 30 through the condensing unit 20. The mask assembly 30 is mounted on the stage 100, and may be moved by the stage driving unit 130. The light source unit 10, the stage 100, and the stage driving unit 130 may be controlled by the control unit 90.

The light 11 incident on the mask assembly 30 may be reflected by the mask assembly 30, and may be incident on the projection unit 40. The projection unit 40 may project the mask pattern (absorption pattern 230 of FIGS. 1 to 17) of the photomask (200 of FIGS. 1 to 17) included in the mask assembly 30 onto a target substrate 50. The target substrate 50 may be a wafer on which integrated circuits are formed. For example, the target substrate 50 may include a photoresist film that is responsive to the light 11. The projection unit 40 may include a projection optical system 42 (e.g., a lens and/or a mirror). The projection optical system 42 may reduce the mask pattern (absorption pattern 230 of FIGS. 1 to 17) of the photomask (200 of FIGS. 1 to 17) included in the mask assembly 30 to a predetermined magnification (for example, 4 times, 6 times, or 8 times) by using the light 11 reflected by the mask assembly 30, and may project the mask pattern onto the target substrate 50.

The target substrate 50 may be mounted on a substrate stage 52. The substrate stage 52 may move the target substrate 50 to change an exposure region (or an exposure position) of the target substrate 50.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

Although the embodiments of the present disclosure have been described above with reference to the accompanying drawings, the present disclosure is not limited to the above embodiments, and may be fabricated in various different forms. Those skilled in the art will appreciate that the present disclosure may be embodied in other specific forms without changing the technical spirit or essential features of the present disclosure. Accordingly, the above-described embodiments should be understood in all respects as illustrative and not restrictive.

What is claimed is:

1. A pellicle cleaning method comprising:
loading a pellicle on a first surface of a stage;
rotating the stage about an axis parallel to the first surface;
electrifying a tip; and
removing particles from the pellicle,
wherein removing of the particles from the pellicle includes pushing of the particles on the pellicle with the electrified tip.

2. The pellicle cleaning method of claim 1,
wherein the removing of the particles from the pellicle is performed after rotating the stage.

3. The pellicle cleaning method of claim 1,
wherein the removing of the particles from the pellicle includes pushing the particles on the pellicle in a horizontal direction with the electrified tip.

4. The pellicle cleaning method of claim 1,
wherein the loading of the pellicle onto the first surface of the stage comprises:
loading the pellicle mounted on a photomask onto the first surface of the stage.

5. The pellicle cleaning method of claim 1,
wherein the loading of the pellicle onto the first surface of the stage comprises:
loading the pellicle mounted on a dummy mask onto the first surface of the stage.

6. The pellicle cleaning method of claim 1,
wherein the loading of the pellicle onto the first surface of the stage comprises:
loading the pellicle directly onto the first surface of the stage.

7. The pellicle cleaning method of claim 1,
wherein the tip includes a first portion and a second portion that are connected to each other and have different slopes of side walls, and
the removing of the particles from the pellicle comprises:
pushing a first particle with the first portion in a horizontal direction, when the size of the first particle is equal to or less than a set value, and
pushing a second particle with the second portion and/or the first portion in the horizontal direction, when the size of the second particle exceeds the set value.

8. A pellicle cleaning method comprising:
loading a pellicle onto an upper surface of a stage;
adjusting a rotary angle of the stage around an axis parallel to the upper surface of the stage;
removing particles from the pellicle, the removing of the particles from the pellicle including pushing the particles on the pellicle in a horizontal direction with a sharp tapered tip;
determining whether the particles are removed from the pellicle; and
removing the particles from the pellicle again, when the particles remain on the pellicle.

9. The pellicle cleaning method of claim 8, further comprising:
electrifying the tip before removing the particles from the pellicle,
wherein the removing of the particles from the pellicle comprises pushing the particles on the pellicle with the electrified tip.

10. The pellicle cleaning method of claim 9, further performing:
the adjusting of the rotary angle of the stage and the electrifying of the tip are performed again when the particles are not removed from the pellicle.

11. The pellicle cleaning method of claim 9,
wherein the particles include a first particle and a second particle, and
re-performing the adjusting of the rotary angle of the stage, the electrifying of the tip, the removing of the particles from the pellicle, the determining whether the particles are removed from the pellicle, and the removing of the particles from the pellicle when the particles are not removed from the pellicle is performed for each of the first particle and the second particle.

12. The pellicle cleaning method of claim 8, further comprising:
re-performing the adjusting of the rotary angle of the stage around the axis parallel to the upper surface, when the particles are not removed from the pellicle.

13. The pellicle cleaning method of claim 8,
wherein the determining whether the particles are removed from the pellicle is checked on the basis of an image of the pellicle.

14. The pellicle cleaning method of claim 8,
wherein the particles include a first particle and a second particle, and
re-performing the adjusting of the rotary angle of the stage, the removing of the particles from the pellicle, the determining whether the particles are removed from the pellicle, and the removing of the particles from the pellicle when the particles are not removed from the pellicle is performed for each of the first particle and the second particle.

15. The pellicle cleaning method of claim 8,
wherein the particles include a first particle and a second particle, and
re-performing the removing of the particles from the pellicle, the determining whether the particles are removed from the pellicle, and the removing of the particles from the pellicle when the particles are not removed from the pellicle is performed for each of the first particle and the second particle.

16. A pellicle cleaning apparatus comprising:
a stage configured to support a pellicle on a first surface;
a stage driver configured to rotate the stage about an axis parallel to the first surface;
a probe which includes a cantilever and a tip provided at an end of the cantilever;
a probe driver configured to move the probe in a vertical direction and a horizontal direction; and
an electrostatic charger,
wherein the tip is configured to contact with the electrostatic charger, be electrified by the probe driver, and push particles on the pellicle.

17. The pellicle cleaning apparatus of claim 16,
wherein the tip has a sharp tapered end.

18. The pellicle cleaning apparatus of claim 16,
wherein the tip includes a first portion and a second portion which are connected to each other and have different slopes of side walls.

19. The pellicle cleaning apparatus of claim 16,
wherein the tip includes a first portion having a first width, and a second portion having a second width different from the first width.

20. The pellicle cleaning apparatus of claim 16, further comprising:
a particle collection tray which overlaps the stage in the vertical direction.
